(19) United States
(12) Patent Application Publication
(10) Pub. No.: US 2025/0132133 A1
(43) Pub. Date: Apr. 24, 2025

(54) GRID FOR SEMICONDUCTOR PROCESS

(71) Applicant: SAMSUNG ELECTRONICS CO., LTD., Suwon-si (KR)

(72) Inventors: Jisoo Im, Suwon-si (KR); Dongwan Kim, Suwon-si (KR); Minsung Kim, Suwon-si (KR); Siyoung Koh, Suwon-si (KR); Younseon Wang, Suwon-si (KR); Junho Im, Suwon-si (KR)

(21) Appl. No.: 18/640,999

(22) Filed: Apr. 19, 2024

(30) Foreign Application Priority Data
Oct. 20, 2023 (KR) 10-2023-0141039

(51) Int. Cl. H01J 37/32; H01J 37/08

(52) U.S. Cl. CPC H01J 37/32422; H01J 37/08

(57) ABSTRACT

A substrate processing apparatus comprises a process chamber, a stage in the process chamber, the stage supporting a substrate, and a grid in the process chamber and upwardly spaced apart from the stage. The grid includes a dielectric plate having a central axis that extends in a first direction, a first electrode plate embedded in the dielectric plate, a second electrode plate downwardly spaced apart from the first electrode plate and embedded in the dielectric plate, and a third electrode plate downwardly spaced apart from the second electrode plate and embedded in the dielectric plate.

### CROSS-REFERENCE TO RELATED APPLICATION

This application claims priority to Korean Patent Application No. 10-2023-0141039, filed in the Korean Intellectual Property Office on Oct. 20, 2023, the disclosure of which is incorporated by reference herein in its entirety.

### BACKGROUND

A semiconductor device may be fabricated by using various processes. For example, a semiconductor device may be manufactured by allowing a silicon wafer to undergo a photolithography process, an etching process, a deposition process, and so forth. An ion beam may be used in an etching process or a deposition process. The ion beam may be generated from an ion beam source. The ion beam source may extract ions from plasma. A grid may be used to extract ions from the plasma. A plurality of grids may be used in an overlapping state. The ion may penetrate an aperture formed in each of the plurality of grids and is outwardly extracted. The ion beam extracted through the grid may be irradiated to a target or a substrate.

### SUMMARY

In general, in some aspects, the disclosed is directed toward a grid for a semiconductor process capable of stably extracting an ion beam from plasma, a substrate processing apparatus including the same, and a substrate processing method using the same.

In general, according to some aspects, the present disclosure is directed to a substrate processing apparatus may comprise: a process chamber; a stage in the process chamber, the stage supporting a substrate; and a grid in the process chamber and upwardly spaced apart from the stage. The grid may include: a dielectric plate having a central axis that extends in a first direction; a first electrode plate embedded in the dielectric plate; a second electrode plate downwardly spaced apart from the first electrode plate and embedded in the dielectric plate; and a third electrode plate downwardly spaced apart from the second electrode plate and embedded in the dielectric plate.

According to some aspects of the present disclosure, a substrate processing apparatus may comprise: a dielectric plate having a central axis that extends in a first direction; a first electrode plate embedded in the dielectric plate; a second electrode plate embedded in the dielectric plate and downwardly spaced apart from the first electrode plate; and a third electrode plate embedded in the dielectric plate and downwardly spaced apart from the second electrode plate. A through hole may be provided to penetrate in the first direction through the dielectric plate so as to connect a top surface of the dielectric plate to a bottom surface of the dielectric plate. A top surface of the first electrode plate and a bottom surface of the third electrode plate may be covered with the dielectric plate.

### BRIEF DESCRIPTION OF DRAWINGS

FIG. 1 illustrates a cross-sectional view showing an example of substrate processing apparatus according to some implementations.

FIG. 2 illustrates a perspective view showing an example of a grid for a semiconductor process according to some implementations.

FIG. 3 illustrates a partially cut perspective view showing an example of a grid for a semiconductor process according to some implementations.

FIG. 4 illustrates an enlarged cross-sectional view along section X of FIG. 1 according to some implementations.

FIG. 5 illustrates a cross-sectional view showing an example of a grid for a semiconductor process according to some implementations.

FIG. 6 illustrates a cross-sectional view showing an example of a grid for a semiconductor process according to some implementations.

FIG. 7 illustrates a cross-sectional view showing an example of a substrate processing apparatus according to some implementations.

FIG. 8 illustrates a flow chart showing an example of a substrate processing method according to some implementations.

FIGS. 9 to 11 illustrate diagrams showing an example of a substrate processing method in accordance with the flow chart of FIG. 8 according to some implementations.

### DETAILED DESCRIPTION

Hereinafter, example implementations will be explained in detail with reference to the accompanying drawings.

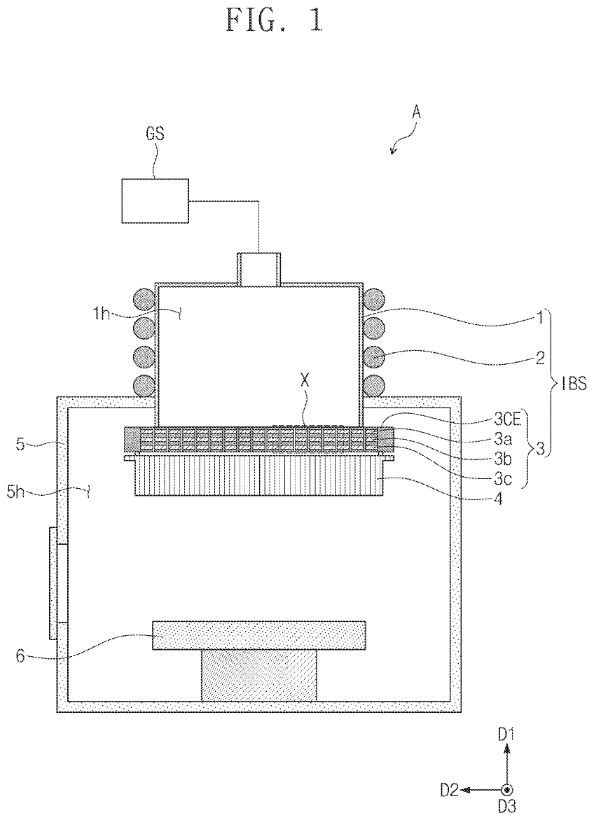

FIG. 1 illustrates a cross-sectional view showing an example of a substrate processing apparatus according to some implementations. In FIG. 1, symbol D1 may indicate a first direction, symbol D2 may indicate a second direction that intersects the first direction D1, and symbol D3 may indicate a third direction that intersects each of the first direction D1 and the second direction D2. The first direction D1 may be called a vertical direction. In addition, each of the second direction D2 and the third direction D3 may be called a horizontal direction.

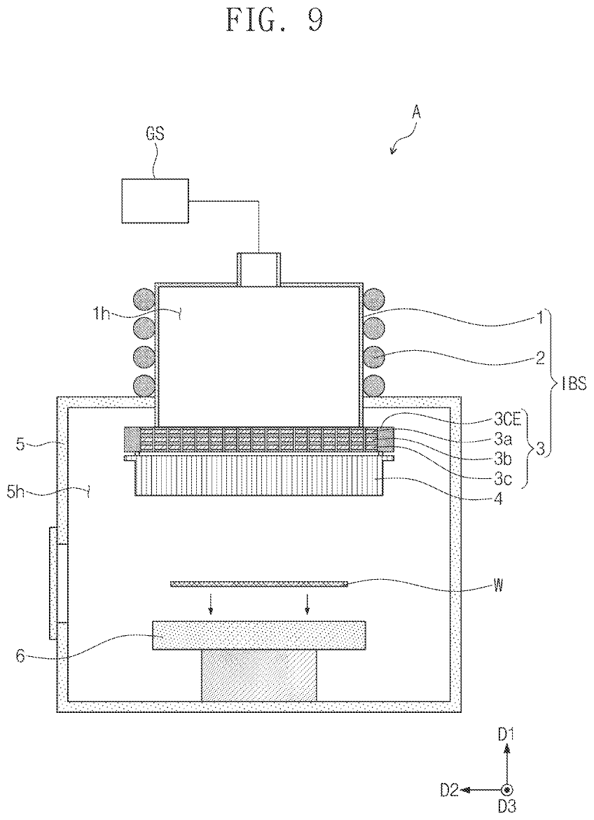

In FIG. 1, the substrate processing apparatus A may be a device that uses an ion beam to process a substrate. For example, the substrate processing apparatus A may be a device that uses an ion beam to perform an etching process on a substrate. In some implementations, the substrate processing apparatus A is not limited thereto, and the substrate processing apparatus A may be a device that performs other kinds of process. For example, the substrate processing apparatus A may be a device configured to perform an ion beam deposition (IBD) process in which an ion beam is used to form a deposition layer. A detailed description thereof will be further discussed below with reference to FIG. 7. In this description, the term “substrate” may refer to a silicon wafer, but the present disclosure is not limited thereto. The substrate processing apparatus A may include an ion beam source IBS, a process chamber 5, a stage 6, and a gas supply GS.

The ion beam source IBS may form an ion beam. For example, the ion beam source IBS may produce the ion beam by extracting ions from plasma. The ion beam released from the ion beam source IBS may move to the process chamber 5. A substrate may be processed by the ion beam. The ion beam source IBS may include a plasma chamber 1, a plasma generator 2, a grid 3 for a semiconductor process, and a reflector 4.

The plasma chamber 1 may provide a plasma generation space 1h. The plasma generation space 1h may be connected to the gas supply GS. A portion of gas supplied from the gas supply GS may be changed into plasma in the plasma generation space 1h.

The plasma generator 2 may be coupled to the plasma chamber 1. The plasma generator 2 may generate plasma in the plasma generation space 1h. The plasma generator 2 may include a radio-frequency (RF) coil. The RF coil may surround the plasma chamber 1. The RF coil may produce an electric field and/or a magnetic field in the plasma generation space 1h. Accordingly, a portion of gas in the plasma generation space 1h may be converted into the plasma. For example, an inductively coupled plasma (ICP) mode may be employed to generate the plasma in the plasma generation space 1h. The present disclosure, however, is not limited thereto, and the plasma generator 2 may include any type of device other than the RF coil.

The grid 3 may be connected to the plasma chamber 1. The grid 3 may extract ions from the plasma in the plasma generation space 1h. The grid 3 may include a dielectric plate 3CE, a first electrode plate 3a, a second electrode plate 3b, and a third electrode plate 3c. The dielectric plate 3CE may have a disk shape having a top surface perpendicular to the first direction D1. The dielectric plate 3CE may surround a top surface of the first electrode plate 3a, a bottom surface of the third electrode plate 3c, and an edge of each of the first electrode plate 3a, the second electrode plate 3b, and the third electrode plate 3c. The dielectric plate 3CE may have a diameter greater than that of each of the first electrode plate 3a, the second electrode plate 3b, and the third electrode plate 3c.

Each of the first electrode plate 3a, the second electrode plate 3b, and the third electrode plate 3c may be positioned embedded in the dielectric plate 3CE. Each of the first electrode plate 3a, the second electrode plate 3b, and the third electrode plate 3c may have a plate shape perpendicular to the first direction D1. For example, each of the first electrode plate 3a, the second electrode plate 3b, and the third electrode plate 3c may have a disk shape. Each of the first electrode plate 3a, the second electrode plate 3b, and the third electrode plate 3c may form an electrode layer. In addition, the first electrode plate 3a, the second electrode plate 3b, and the third electrode plate 3c may be arranged in the first direction D1. For example, the second electrode plate 3b may be disposed downwardly spaced apart from the first electrode plate 3a. The third electrode plate 3c may be disposed downwardly spaced apart from the second electrode plate 3b. The top surface of the first electrode plate 3a and the bottom surface of the third electrode plate 3c may be covered with the dielectric plate 3CE. The ions extracted from the plasma in the plasma generation space 1h may sequentially pass through the first electrode plate 3a, the second electrode plate 3b, and the third electrode plate 3c, thereby moving to the process chamber 5. Each of the first electrode plate 3a, the second electrode plate 3b, and the third electrode plate 3c may include one of tungsten (W) or platinum (Pt), but the present disclosure is not limited thereto. Although it is illustrated and described that three grids are provided, the present disclosure is not limited thereto. The first electrode plate 3a, the second electrode plate 3b, and the third electrode plate 3c will be further discussed in detail below.

The reflector 4 may be disposed below the grid 3. The reflector 4 may convert the ion beam into a neutral beam. For example, the reflector 4 may reflect and convert the extracted ion beam into the neutral beam. The reflector 4 may be connected through a support member (not designated by reference numeral) to the grid 3.

The process chamber 5 may provide a process space 5h. A substrate may be processed in the process space 5h. The process chamber 5 may be connected to the ion beam source IBS. For example, the ion beam source IBS may be coupled to one side of the process chamber 5. The plasma generation space 1h and the process space 5h may be connected to each other through the grid 3. The present disclosure, however, is not limited thereto, and the process chamber 5 may surround the ion beam source IBS. Alternatively, the process chamber 5 and the ion beam source IBS may be disposed spaced apart from each other.

The stage 6 may be disposed in the process chamber 5. The stage 6 may be spaced apart from the ion beam source IBS. For example, as shown in FIG. 1, the stage 6 may be downwardly spaced apart from the ion beam source IBS. The stage 6 may support a substrate. For example, the stage 6 may rigidly hold a substrate on a certain position in the process space 5h. The stage 6 may include an electrostatic chuck (ESC) and/or a vacuum chuck. The present inventive concepts, however, are not limited thereto, and a substrate may be disposed on the stage 6 with no fixing force.

The gas supply GS may be connected to the plasma generation space 1h. The gas supply GS may supply the plasma chamber 1 with a process gas. The gas supply GS may include a gas tank, a compressor, and a valve.

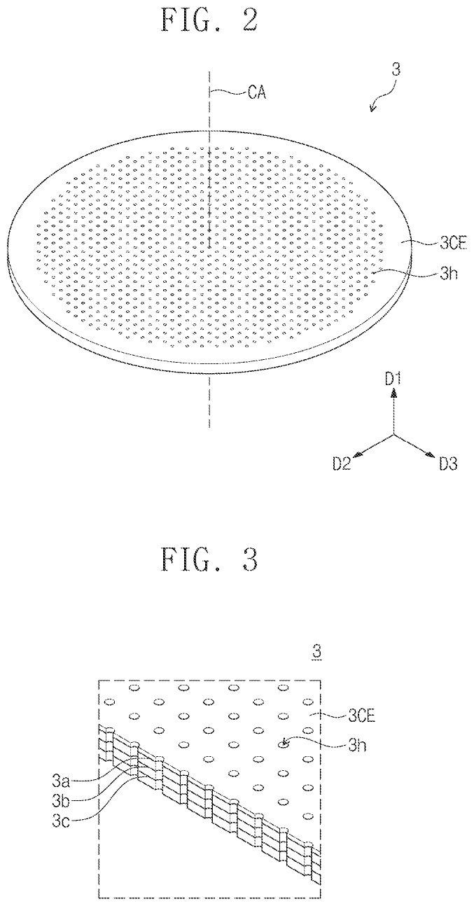

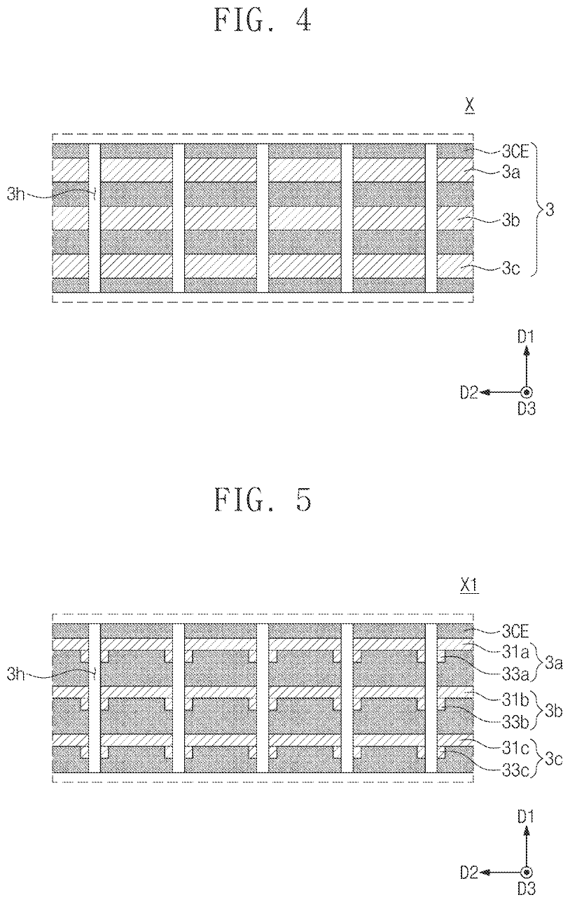

FIG. 2 illustrates a perspective view showing an example of a grid for a semiconductor process according to some implementations. FIG. 3 illustrates a partially cut perspective view showing an example of a grid for a semiconductor process according to some implementations. For convenience, the following descriptions may omit descriptions of components that are substantially the same as or similar to those discussed with reference to FIG. 1.

In FIG. 2, the grid 3 may have a central axis CA that extends in the first direction D1. The grid 3 may have a circular shape when viewed in plan. The grid 3 may provide a through hole 3h. The through hole 3h may be provided in plural. The plurality of through holes 3h may be disposed spaced apart from each other in the horizontal direction, but the present disclosure is not limited thereto. A single through hole 3h will be discussed in the interest of convenience. The through hole 3h will be discussed in detail below with reference to FIG. 3.

In FIG. 3, the through hole 3h may extend in the first direction D1. For example, the through hole 3h may penetrate in the first direction D1 through the dielectric plate 3CE to connect to each other top and bottom surfaces of the dielectric plate 3CE. The through hole 3h may have a circular shape when viewed in plan. The plasma may pass through the through hole 3h to extract the ion beam.

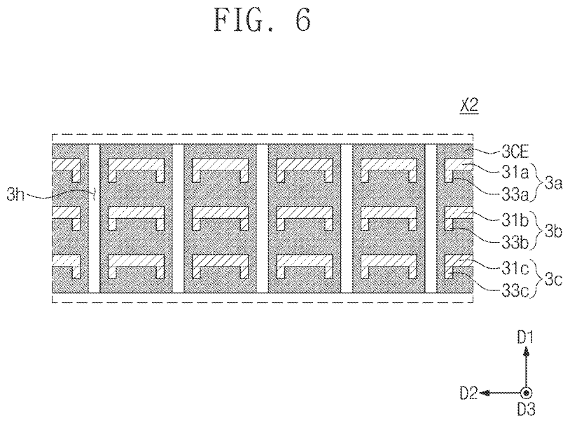

FIG. 4 illustrates an enlarged cross-sectional view along section X of FIG. 1 according to some implementations. For convenience, the following descriptions may omit descriptions of components that are substantially the same as or similar to those discussed with reference to FIGS. 1 to 3.

In FIG. 4, the dielectric plate 3CE may have a thickness of about 1 mm to about 3 mm, but the present disclosure is not limited thereto. The dielectric plate 3CE may include a ceramic. For example, the dielectric plate 3CE may include Al₂O₃.

The first electrode plate 3a, the second electrode plate 3b, and the third electrode plate 3c may be embedded in the dielectric plate 3CE. The first electrode plate 3a, the second electrode plate 3b, and the third electrode plate 3c may have their top surfaces each of which has a disk shape perpendicular to the first direction D1. The first electrode plate 3a, the second electrode plate 3b, and the third electrode plate 3c may be stacked in the first direction D1. A positive voltage may be applied to the first electrode plate 3a. For example, the first electrode plate 3a may extract positive ions. A negative voltage may be applied to the second electrode plate 3b. For example, the second electrode plate 3b may accelerate ions. The third electrode plate 3c may be electrically grounded. For example, the third electrode plate 3c may prevent reverse movement of ions. Each of the first electrode plate 3a, the second electrode plate 3b, and the third electrode plate 3c may include one of tungsten (W) or platinum (Pt), but the present inventive concepts are not limited thereto. Each of the first electrode plate 3a, the second electrode plate 3b, and the third electrode plate 3c may have a thickness of about 5 μm to about 30 μm, but the present inventive concepts are not limited thereto.

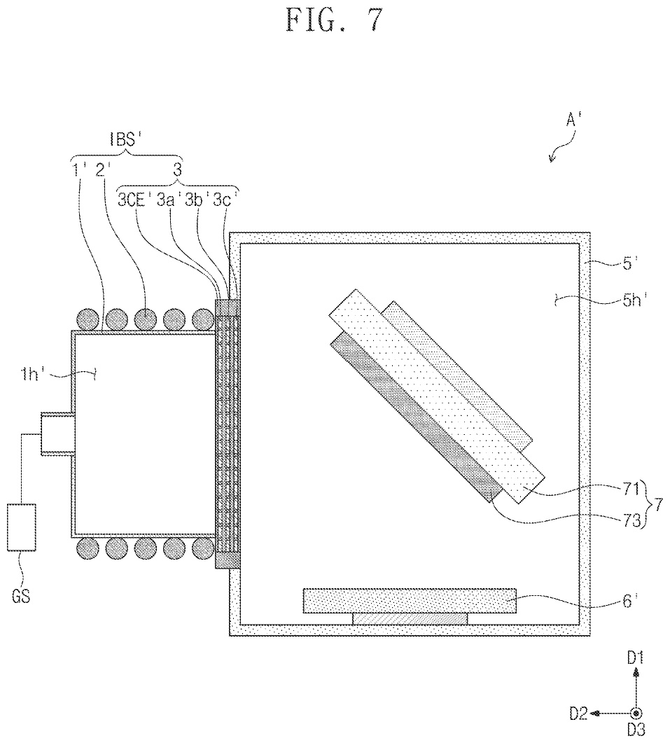

FIG. 5 illustrates a cross-sectional view showing an example of a grid for a semiconductor process according to some implementations. For convenience, the following descriptions may omit descriptions of components that are substantially the same as or similar to those discussed with reference to FIGS. 1 to 4.

In FIG. 5, the first electrode plate 3a may include a first electrode body 31a and a via metal 33a. The first electrode body 31a may have a disk shape having a central axis parallel to the first direction D1. The via metal 33a may extend in the first direction D1 from the first electrode body 31a. The via metal 33a may be provided in plural. A single via metal 33a will be discussed below in the interest of convenience. The via metal 33a may surround the through hole 3h. For example, the through hole 3h may penetrate in the first direction D1 through the first electrode body 31a and the via metal 33a. The via metal 33a may cause to allow the first electrode plate 3a around the through hole 3h to have a thickness the same as a sum of thicknesses of the via metal 33a and the first electrode body 31a. The first electrode body 31a and the via metal 33a may be exposed toward the through hole 3h. For example, the first electrode body 31a and the via metal 33a may have their lateral surfaces (not designated by reference numerals) each of which is exposed to the through hole 3h. A thickness of the first electrode plate 3a at a position that is adjacent to the through hole 3h may be greater than that of the first electrode plate 3a at a position that is not adjacent to the through hole 3h.

The second electrode plate 3b may include a second electrode body 31b and a via metal 33b. The third electrode plate 3c may include a third electrode body 31c and a via metal 33c. Each of the second electrode body 31b and the third electrode body 31c may be substantially the same as or similar to the first electrode body 31a.

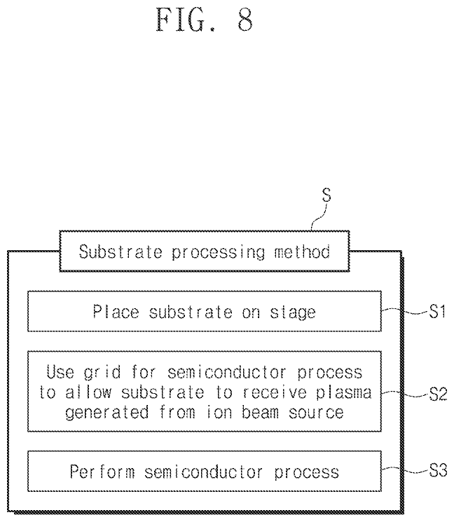

FIG. 6 illustrates a cross-sectional view showing an example of a grid for a semiconductor process according to some implementations. For convenience, the following descriptions may omit descriptions of components that are substantially the same as or similar to those discussed with reference to FIGS. 1 to 5.

In FIG. 6, the first electrode body 31a and the via metal 33a may be completely surrounded by the dielectric plate 3CE. For example, the first electrode body 31a and the via metal 33a may be spaced apart in the horizontal direction from the through hole 3h, and may not be exposed by the through hole 3h.

FIG. 7 illustrates a cross-sectional view showing an example of a substrate processing apparatus according to some implementations. For convenience, the following descriptions may omit descriptions of components that are substantially the same as or similar to that with reference to FIGS. 1 to 6.

In FIG. 7, a substrate processing apparatus A′ may be provided. The substrate processing apparatus A′ may be a device that performs a deposition process on a substrate. For example, the substrate processing apparatus A′ may be a device configured to perform an ion beam deposition process in which an ion beam is used to form a deposition layer. The substrate processing apparatus A′ may include an ion beam source IBS′, a process chamber 5′, a target part 7, a stage 6′, and a gas supply GS′.

The ion beam source IBS′ may include a plasma chamber 1′, a plasma generator 2′, a grid 3′ for a semiconductor process. The plasma chamber 1′, the plasma generator 2′, and the grid 3′ may be substantially the same as or similar to those discussed with reference to FIG. 1.

The target part 7 may be spaced apart from the ion beam source IBS′ and the stage 6′. The target part 7 may include a target plate 73 and a target holder 71.

The target plate 73 may include a target material. The target material may be a material that is intended to be deposited on a substrate disposed on the stage 6′. The target plate 73 may have a circular shape, but the present inventive concepts are not limited thereto. The target holder 71 may support the target plate 73. In a state that the target plate 73 is disposed on the target holder 71, an ion beam may be irradiated from the ion beam source IBS′ to the target plate 73. The ion beam may sputter the target material from the target plate 73. The sputtered target material may be move to the substrate on the stage 6′. Therefore, a deposition may be formed on the substrate.

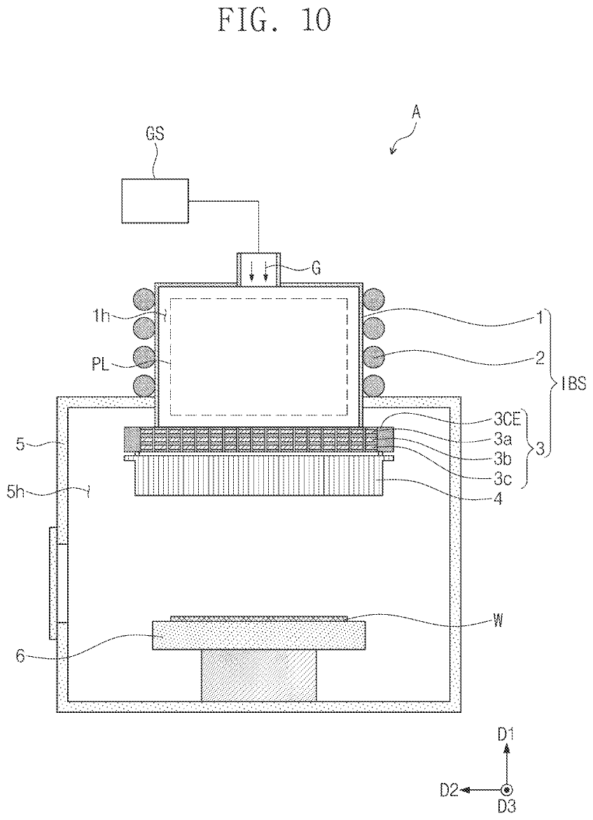

FIG. 8 illustrates a flow chart showing an example of a substrate processing method according to some implementations. In FIG. 8, a substrate processing method S may be provided. The substrate processing method S may be a way of processing a substrate by using the substrate processing apparatus A discussed with reference to FIGS. 1 to 6. The substrate processing method S may include placing a substrate on a stage (S1), using a grid for a semiconductor process to allow the substrate to receive plasma generated from an ion beam source (S2), and performing the semiconductor process (S3).

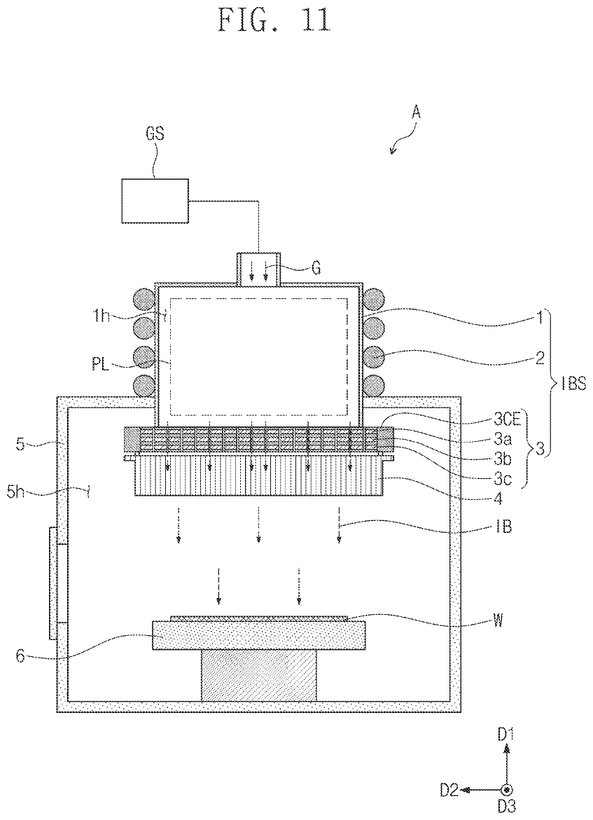

FIGS. 9 to 11 illustrate diagrams showing an example of a substrate processing method in accordance with the flow chart of FIG. 8 according to some implementations. In FIGS. 8 and 9, the step S1 of placing a substrate W on the stage 6 may include rigidly placing the substrate W on a top surface of the stage 6 in the substrate processing apparatus A. For example, the stage 6 may use an electrostatic force and/or a vacuum pressure to fix the substrate W on a certain position in the process space 5h. The substrate W on the stage 6 may be spaced apart from the ion beam source IBS. The substrate W may include a silicon wafer, but the present inventive concepts are not limited thereto.

In FIGS. 8, 10, and 11, a process gas G may be supplied from the gas supply GS to the plasma chamber 1. A portion of the process gas G in the plasma generation space 1h may be converted into a plasma PL by the plasma generator 2. The step S2 of using the grid 3 for a semiconductor process to allow the substrate W to receive the plasma PL generated from the ion beam source IBS and the step S3 of performing the semiconductor process may include allowing the grid 3 to extract an ion beam IB from the plasma PL. For example, the ion beam IB may sequentially pass through the first electrode plate 3a, the second electrode plate 3b, and the third electrode plate 3c, thereby moving to the process space 5h. The ion beam IB extracted through the grid 3 may be irradiated to the substrate W. For example, the ion beam W may etch the substrate W.

According to a grid for a semiconductor process, a substrate processing apparatus including the same, and a substrate processing method using the same in accordance with some implementations of the present disclosure, an ion beam may be effectively extracted from an ion beam source. For example, a plurality of electrode plates may be embedded in a dielectric plate to provide a single grid for a semiconductor process. Accordingly, there may be a reduction in probability of dielectric breakdown. In addition, a through hole of the grid may be aligned in a straight line. When the through hole is not aligned in a straight line, the extracted ion beam may have a poor quality. Thus, the plurality of electrode plates may be embedded in the dielectric plate to effectively extract the ion beam from the ion beam source. Moreover, the electrode plate may decrease in probability of fracture.

According to a grid for a semiconductor process, a substrate processing apparatus including the same, and a substrate processing method using the same in accordance with some implementations of the present disclosure, it may be possible to flexibly cope with various kinds of process. For example, it may be possible to differently apply ion beam energy to cope with a process recipe that is changed based on kinds of substrate. Accordingly, a single apparatus may be used to perform various processes.

According to a grid for a semiconductor process, a substrate processing apparatus including the same, and a substrate processing method using the same of the present disclosure, it may be possible to stably extract an ion beam.

According to a grid for a semiconductor process, a substrate processing apparatus including the same, and a substrate processing method using the same of the present disclosure, it may be possible to flexibly cope with various kinds of process.

While this disclosure contains many specific implementation details, these should not be construed as limitations on the scope of what may be claimed. Certain features that are described in this disclosure in the context of separate implementations can also be implemented in combination in a single implementation. Conversely, various features that are described in the context of a single implementation can also be implemented in multiple implementations separately or in any suitable subcombination. Moreover, although features may be described above as acting in certain combinations, one or more features from a combination can in some cases be excised from the combination, and the combination may be directed to a subcombination or variation of a subcombination.

What is claimed is:

1. A substrate processing apparatus comprising:
a process chamber;
a stage in the process chamber, the stage configured to support a substrate; and
a grid spaced apart from the stage in the process chamber,
wherein the grid includes:
a dielectric plate having a central axis that extends in a first direction;
a first electrode plate embedded in the dielectric plate;
a second electrode plate spaced apart from the first electrode plate and embedded in the dielectric plate; and
a third electrode plate spaced apart from the second electrode plate and embedded in the dielectric plate.

2. The substrate processing apparatus of claim 1, wherein the dielectric plate has a disk shape having a top surface perpendicular to the first direction.

3. The substrate processing apparatus of claim 1, wherein the grid includes a plurality of through holes that extend in the first direction through the dielectric plate, the first electrode plate, the second electrode plate, and the third electrode plate.

4. The substrate processing apparatus of claim 3, wherein a thickness of the dielectric plate is in a range of 1 mm to 3 mm.

5. The substrate processing apparatus of claim 1, further comprising a reflector disposed below the grid.

6. The substrate processing apparatus of claim 1, further comprising an ion beam source disposed on the grid,
wherein the ion beam source includes a plasma chamber and a plasma generator that surrounds the plasma chamber.

7. The substrate processing apparatus of claim 1, wherein a diameter of the dielectric plate is greater than a diameter of each of the first electrode plate, the second electrode plate, and the third electrode plate.

8. The substrate processing apparatus of claim 1, wherein the dielectric plate includes a ceramic.

9. The substrate processing apparatus of claim 3, wherein the first electrode plate includes:
a disk-shape first electrode body; and
a plurality of via metals that extend in the first direction from the first electrode body and surround the plurality of through holes.

10. The substrate processing apparatus of claim 1, wherein each of the first electrode plate, the second electrode plate, and the third electrode plate includes one of tungsten (W) or platinum (Pt).

11. The substrate processing apparatus of claim 1, wherein the dielectric plate surrounds a top surface of the first electrode plate, a bottom surface of the second electrode plate, and an edge of each of the first electrode plate, the second electrode plate, and the third electrode plate.

12. A substrate processing apparatus comprising:
a dielectric plate having a central axis that extends in a first direction;
a first electrode plate embedded in the dielectric plate;
a second electrode plate embedded in the dielectric plate and spaced apart from the first electrode plate; and
a third electrode plate embedded in the dielectric plate and spaced apart from the second electrode plate,
wherein a through hole extends in the first direction through the dielectric plate and from a top surface of the dielectric plate to a bottom surface of the dielectric plate, and
wherein a top surface of the first electrode plate and a bottom surface of the third electrode plate are covered with the dielectric plate.

13. The substrate processing apparatus of claim 12,
wherein the through hole comprises a plurality of through holes,
wherein the plurality of through holes are spaced apart in a horizontal direction.

14. The substrate processing apparatus of claim 12, wherein a diameter of the dielectric plate is greater than a diameter of each of the first electrode plate, the second electrode plate, and the third electrode plate.

15. The substrate processing apparatus of claim 12,
wherein the first electrode plate includes:
a disk-shape first electrode body; and
a via metal that extends in the first direction from the first electrode body,
wherein the through hole extends in the first direction through the first electrode body and the via metal.

16. The substrate processing apparatus of claim 15, wherein the first electrode body and the via metal are exposed by the through hole.

17. The substrate processing apparatus of claim 12,
wherein the first electrode plate includes:
a disk-shape first electrode body; and
a via metal that extends in the first direction from the first electrode body,
wherein the first electrode body and the via metal are spaced apart in a horizontal direction from the through hole and are not exposed by the through hole.

18. The substrate processing apparatus of claim 12, wherein each of the first electrode plate, the second electrode plate, and the third electrode plate includes one of tungsten (W) or platinum (Pt).

19. The substrate processing apparatus of claim 12, a thickness of each of the first electrode plate, the second electrode plate, and the third electrode plate is in a range of 5 μm to 30μm.

20. The substrate processing apparatus of claim 12, wherein the dielectric plate includes a ceramic.
